(19) United States
(12) Patent Application Publication
(10) Pub. No.: US 2002/0180038 A1
(43) Pub. Date: Dec. 5, 2002

(54) Inductor and method of manufacturing the same

(75) Inventors: Hisato Oshima, Fukui-shi (JP); Takashi Shikama, Yokaichi-shi (JP); Iwao Fukutani, Shiga-ken (JP); Kenichi Saito, Fukui-ken (JP)

Correspondence Address: Keating & Bennett LLP, Suite 312, 10400 Eaton Place, Fairfax, VA, 22030, US

(73) Assignee: Murata Manufacturing Co., Ltd., Nagaokakyo-shi (JP)

(21) Appl. No.: 10/100,120

(22) Filed: Mar. 19, 2002

(30) Foreign Application Priority Data
Apr. 20, 2001 (JP) 2001-123089

(51) Int. Cl. H01L 23/06

(52) U.S. Cl. 257/729

(57) ABSTRACT

An inductor and a manufacturing method for the inductor includes disposing a spacer pin defining a core, and which includes a magnetic sinter, in a mold, and placing a coil so as to surround the spacer pin. A composite material which has a permeability that is different from that of the magnetic sinter and which includes a mixture of a powdered magnetic material and a resin, is then injected into the mold to obtain a molded body having embedded therein the coil and the spacer pin. Next, external electrodes are formed on outside surfaces of the molded body such that both ends of the coil are connected to the external electrodes.

### BACKGROUND OF THE INVENTION

1. Field of the Invention

The present invention relates to an inductor used for eliminating noise produced in, for example, large current applications, and to a manufacturing method thereof. More particularly, the present invention relates to an inductor including a coil and a core embedded inside a resin mold and to a manufacturing method thereof.

2. Description of the Related Art

Conventionally, inductors including a metallic coil of copper wire have been used as components for eliminating noise in large current applications. With reference to FIG. 7, an explanation is provided of an example of a manufacturing method of a conventional inductor.

First, a coil 51, shown in FIG. 7, is prepared. The coil 51 includes a tightly wound insulated copper wire, such that there are no gaps between adjacent turns of the insulated copper wire.

A mold 52 includes an upper mold portion 53 and a lower mold portion 54. The upper mold portion 53 and the lower mold portion 54 define a cylindrical molding cavity 55. A through-hole 54a is provided in the base of the lower mold portion 54. A protection pin 56 is inserted into the molding cavity 55 via the through-hole 54a. The upper end of the protection pin 56 abuts against the inside surface of the upper mold portion 53.

Initially, the upper mold portion 53 is separated from the lower mold portion 54 and the coil 51 is wound around protection pin 56.

Subsequently, the upper mold portion 53 mates with the lower mold portion 54 to define the molding cavity 55. In this state, a composite material made by mixing a synthetic resin and ferrite is injected into the molding cavity 55 via a resin-injection hole 54b provided in the lower mold portion 54, and is molded. Then, the protection pin 56 is removed from the lower mold portion 54, and a composite material, which is the same as the one mentioned above, is injected via a resin-injection hole 53a provided in the upper mold portion 53, and is molded.

With this manufacturing method, the coil 51 is embedded in a molded body 57. Next, both ends of the molded body are polished to expose the ends 51a and 51b of the coil 51 and to remove the insulation at the ends 51a and 51b. External electrodes are then provided on both end-surfaces of the molded body 57 to produce an inductor.

In the conventional method of manufacturing an inductor, the areas inside and outside of the coil 51 are formed by injection molding of essentially identical composite materials. Consequently, it is difficult to obtain inductors having various impedances.

For example, to increase the impedance of an inductor without increasing the size, only methods wherein the number of turns of the coil 51 is increased, or the magnetic permeability (hereinafter referred to simply as permeability) of the composite material is increased, have been successful.

However, in order to increase the number of turns, the diameter of the copper wire defining the coil 51 must be reduced. As a result, the DC resistance increases dramatically which causes the current-carrying capacity of the inductor to decrease dramatically.

Furthermore, in order to increase the permeability of the composite material, the magnetic material content in the composite material must be increased. If the content of the magnetic material of the composite material is increased, the viscosity of the composite material before injection molding increases and injection molding is much more difficult.

That is to say, in the conventional method of manufacturing an inductor, it is extremely difficult to increase the impedance of the inductor and to achieve various impedance values. By adjusting the composition and the grain particle diameter of the powdered magnetic material of the composite material, the impedance can be changed. However, it is not possible to significantly change the impedance.

### SUMMARY OF THE INVENTION

In order to overcome the above-described problems, preferred embodiments of the present invention provide an inductor in which a wide range of impedances can be achieved, in which a very large impedance is achieved without increasing the size of the inductor, and a manufacturing method thereof.

A method of manufacturing an inductor includes the steps of providing a spacer pin including magnetic sinter in a mold and providing a coil to surround the spacer pin. A composite material which has a permeability that is different from that of the magnetic sinter of the spacer pin and which includes a mixture of a powdered magnetic material and a resin is injected into the mold and a molded body having embedded therein the coil and the spacer pin is obtained. Next, external electrodes are formed on outside surfaces of the molded body such that both ends of the coil are connected to the external electrodes.

Preferably, a spacer-pin insertion hole for inserting the spacer pin into the mold is provided in the mold. The spacer pin is pushed by the next spacer pin through this spacer-pin insertion hole and is disposed in the mold.

More specifically, the spacer pin is pushed by another spacer pin, which is used in the production of the next inductor, through the spacer-pin insertion hole and is disposed inside the mold. The spacer pin is thereby accurately positioned inside the mold. Additionally, after the production of one inductor, the next spacer pin is then pushed by the spacer pin of the subsequent inductor and is disposed inside of the mold. As a result, the productivity of inductors is greatly improved when they are being produced continuously.

The inductor according to preferred embodiments of the present invention includes a molded body obtained by molding a composite material including a mixture of a powdered magnetic material and a resin. The inductor further includes a core embedded in the molded body, the core including a magnetic sinter that has a permeability different from that of the composite material defining the molded body, and a coil, which is disposed to surround the core, and which is embedded in the molded body such that both ends of the coil are exposed at the outside surfaces of the molded body. Additionally, the inductor includes a plurality of external electrodes provided on the outside surfaces of the molded body such that both ends of the coil are electrically connected to the electrodes.

Other features, elements, characteristics and advantages of the present invention will become more apparent from the following detailed description of preferred embodiments thereof with reference to the attached drawings.

### BRIEF DESCRIPTION OF THE DRAWINGS

FIG. 1 is a sectional view showing a coil and a spacer pin disposed inside a lower mold portion, according to a preferred embodiment of the present invention.

FIG. 2 is a sectional view showing an injection molding process according to a preferred embodiment of the present invention.

FIG. 3 is a sectional view showing a process wherein the upper mold portion is detached and the spacer pin raised, according to a preferred embodiment of the present invention.

FIG. 4 is a sectional view showing the spacer pin that is moved upward from a predetermined position of the molded body, according to a preferred embodiment of the present invention.

FIG. 5 is a sectional view showing a process wherein the molded body having the spacer pin and a coil embedded therein is removed from the mold.

FIG. 6 is a sectional view showing the inductor obtained according to a preferred embodiment of the present invention.

FIG. 7 is a sectional showing an example of a conventional manufacturing method of an inductor.

### DETAILED DESCRIPTION OF PREFERRED EMBODIMENTS

Preferred embodiments of the present invention will be with reference to the figures.

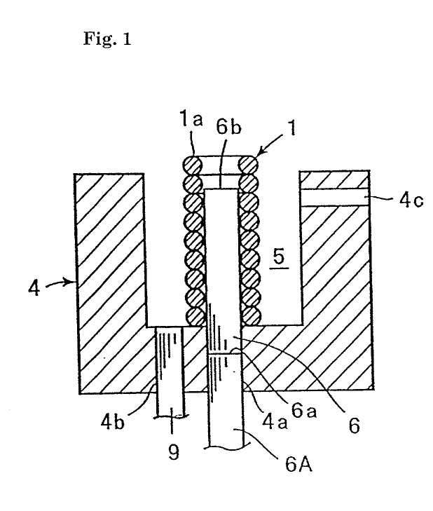

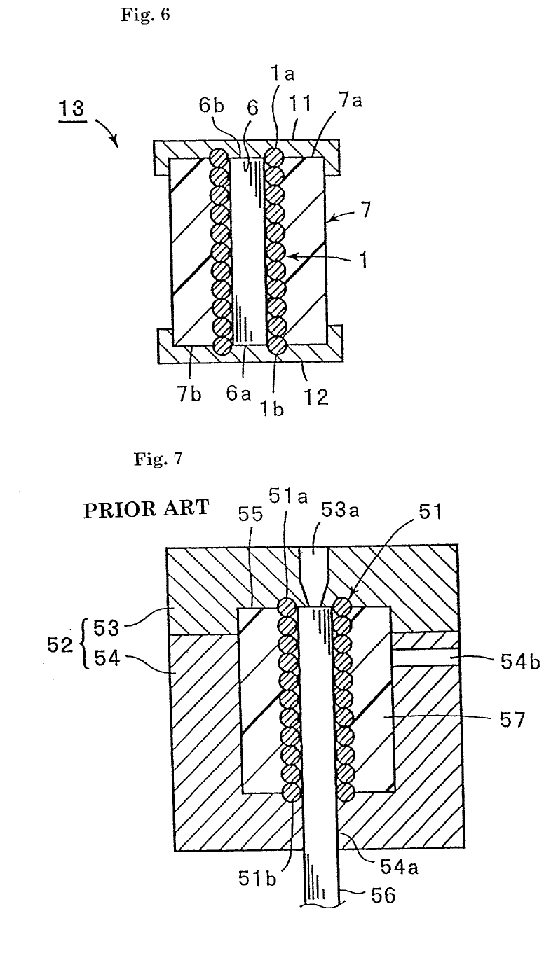

FIGS. 1 to 5 are sectional views that illustrate the manufacturing method according to a preferred embodiment of the present invention. FIG. 6 is a sectional view of the inductor according to another preferred embodiment.

In the manufacturing method according to a preferred embodiment of the present invention, a coil 1 including a wound insulated conductor wire is provided. The conductor wire is made of any suitable metal, such as copper, silver or gold, or alloys thereof. Additionally, the coil 1 preferably includes a conductor wire that is tightly wound without any gaps between adjacent turns. By winding the conductor wire such that there are no gaps, differences in gaps between the conductor wire during the hereinafter-described resin injection is prevented and an inductor having minimal variations in impedance is obtained.

However, where the number of turns is adjusted to change the impedance, the coil 1 may also be formed such that there are gaps between the conductor wire when it is wound.

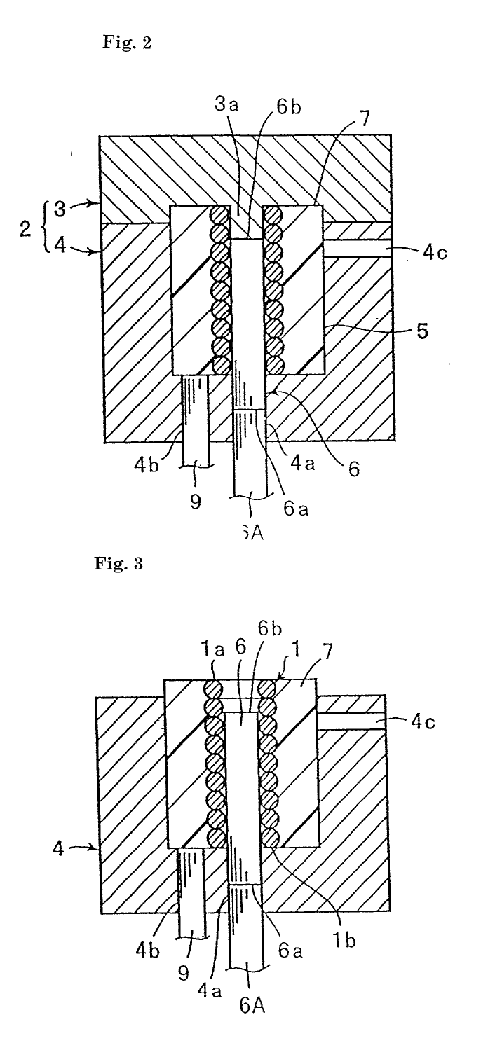

This preferred embodiment uses a mold 2, shown in FIG. 2. The mold 2 includes an upper mold portion 3 and a lower mold portion 4. As shown in FIG. 2, the upper mold portion 3 and the lower mold portion 4 define a substantially cylindrical molding cavity 5.

Additionally, a spacer-pin insertion hole 4a and a pin insertion hole 4b are provided at the bottom surface of the lower mold portion 4 such that they penetrate the lower mold portion 4. The upper end of the spacer-pin insertion hole 4a opens at the approximate center of the substantially cylindrical molding cavity 5. The upper end of the pin insertion hole 4b opens at a position at the bottom surface of the molding cavity 5 that is spaced from the approximate center of the molding cavity 5. Additionally, a resin-injection hole 4c is provided in the side wall of the lower mold portion 4. The resin-injection hole 4c is provided in order to inject composite material into the molding cavity 5.

First, as shown in FIG. 1, a substantially cylindrical spacer pin 6 is inserted into the lower mold portion 4 via the spacer-pin insertion hole 4a. The spacer pin 6 defines the core of the inductor, and is a magnetic sinter. The length of the spacer pin 6 is shorter than that of the coil 1.

In addition, the lower end 6a of the spacer pin 6 is arranged such that it is pushed by a spacer pin 6A, which is to be used in the next inductor, and the spacer pin 6 is thereby inserted. The spacer 6 may be made of a magnetic sinter of various magnetic materials, such as a ferrite sinter. However, this magnetic sinter is selected such that its permeability is different from that of the composite material, which will be described later.

As shown in FIG. 1, the spacer pin 6 is inserted such that the upper end 6b of the spacer pin 6 is positioned below the upper end la of the coil 1.

Additionally, a pin 9 is inserted into the pin-insertion hole 4b. The pin 9 is disposed such that the upper end of the pin 9 does not protrude from the pin-insertion hole 4.

Next, as shown in FIG. 2, the upper mold portion 3 and the lower mold portion 4 are mated to define the molding cavity 5. A projection 3a, which has a diameter that is substantially equal to or smaller than that of the internal diameter of the coil 1, is provided in the approximate center at the bottom surface of the upper mold portion 3. The length of this projection 3a is selected such that the tip of the projection 3a abuts against the upper end 6b of the spacer pin 6.

Consequently, as shown in FIG. 2, when the mold 2 is closed, the tip of the projection 3a of upper mold portion 3 abuts against the upper end 6b of the spacer pin 6.

Next, a composite material is injected via the injection hole 4c and is molded. In this preferred embodiment, a material including a mixture of a powdered magnetic material and a resin is preferably used. As the powdered magnetic material, suitable powdered magnetic material such as ferrite powder is preferably used. As the resin, suitable synthetic resins such as polyphenylene sulphide (PPS), liquid crystal polymer (LCP), polyacetal (PA) are preferably used. It is necessary that the composite material be selected such that the permeability of the molded body including the composite material is different from that of the spacer pin 6 including the above-discussed magnetic sinter.

A molded body 7 corresponding to the shape of the molding cavity 5 is formed around the coil 1 by injection molding.

Next, the upper mold portion 3 is separated from the lower mold portion 4, as seen in FIG. 3.

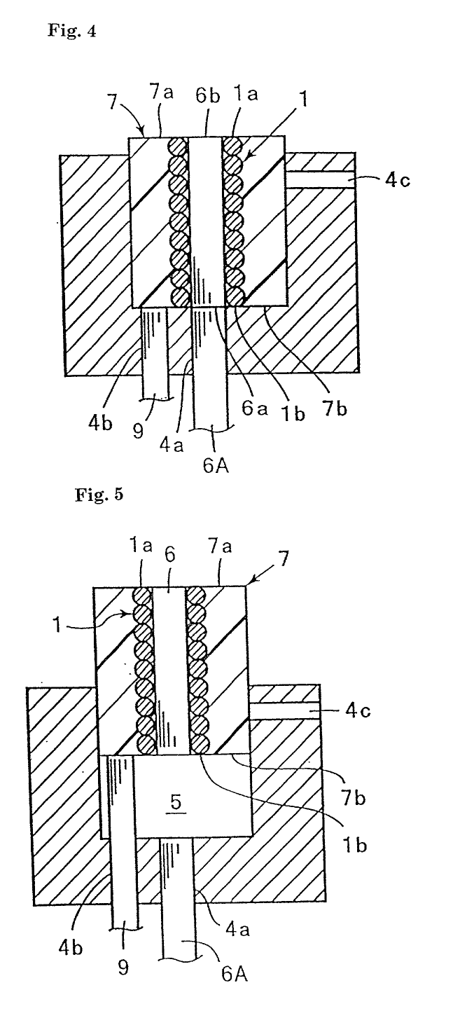

The spacer pin 6 is then pushed by the next spacer pin 6A and is moved upward. Consequently, as shown in FIG. 4, the spacer pin 6 is disposed such that it extends from the upper end-surface 7a of the molded body 7 to the lower end-surface 7b.

Next, as shown in FIG. 5, the pin 9 is moved upward such that it extends into the molding cavity 5. As a result, the molded body 7 having the coil 1 and the spacer pin 6 is pushed out of the lower mold portion 4.

Subsequently, the upper end-surface 7a and the lower end-surface 7b of the molded body 7 shown in FIG. 5 are polished by a suitable polishing method such as sandblasting, to expose the upper end la and the lower end 1b of the coil 1, and to remove the insulation of the conductor wire defining the coil.

Next, external electrodes 11 and 12 shown in FIG. 6 are arranged such that they cover the upper end-surface 7a and the lower end-surface 7b of the molded body 7, respectively. The external electrodes 11 and 12 may be formed by any suitable method, such as plating, applying and curing conductive paste.

As shown in FIG. 6, in the inductor 13 according to the present preferred embodiment, the coil 1 is embedded inside the molded body 7, and the spacer pin 6 including a magnetic sinter is disposed inside the coil 1. This spacer pin 6 functions as a magnetic core. The permeability of the spacer pin 6 is different from that of the molded body 7 including composite material. Consequently, by using various combinations of composite material and magnetic sinter, inductors having various impedances are easily obtained.

Next, an explanation of a specific example according to preferred embodiments of the present invention is provided.

A composite material including a mixture of about 100 parts by weight of PPS (polyphenylene sulphide) resin and about 85 parts by weight of powdered Ni—Cu—Zn ferrite was prepared. The permeability of the molded body including this composite material was about 10.

Additionally, a coil 1 having a length of approximately 4.5 mm and an internal diameter of approximately 1.8 mm was formed by tightly winding an insulated copper wire having a diameter of about 0.2 mm such that there were no gaps between adjacent turns.

Ni—Cu—Zn ferrite sinter rods having permeabilities of about 1000, about 500, about 100, about 50, and about 10 were prepared for the spacer pin 6. The external diameter of the rod was approximately 1.8 mm, and the length was approximately 4.5 mm.

Following the manufacturing method shown in FIGS. 1 to 6, the inductors below having sample numbers 1 to 5 were obtained by using the corresponding materials mentioned above. Furthermore, the external electrodes 11 and 12 were provided by sequential electroplating of a Cu metal plating film, an Ni metal plating film, and an Sn metal plating film.

For comparison, the composite material and the coil 1 were prepared, and following the conventional method shown in FIG. 7, an inductor was manufactured. Namely, a conventional inductor wherein a molded body portion including the composite material is also provided inside the coil was manufactured.

The impedance at about 100 MHz of each of the inductors obtained as described above was measured. The results are as shown below in Table 1.

TABLE 1

(Ω)

| | Sample | Sample | Sample | Sample | Sample | Conventional |
|---|---|---|---|---|---|---|
| | 1 | 2 | 3 | 4 | 5 | Example |
| Permea- | 1000 | 500 | 100 | 50 | 10 | Permeability |
| bility | | | | | | of composite |
| of Core | | | | | | material |
| | | | | | | without core |
| | | | | | | 10 |
| Impedance | 1750 | 1450 | 1200 | 915 | 720 | 715 |
| (Ω) (at | | | | | | |
| 100 MHz) | | | | | | |

In contrast to a maximum impedance of about 715 Ω in the conventional inductor, in each of the sample inductors 1 to 4, by adjusting the permeability of the spacer pin, an increased impedance is obtained. Thus, by using different spacer pins 6 having various permeabilities, various impedances are easily obtained.

In the method of manufacturing an inductor according to preferred embodiments of the present invention, the spacer pin including a magnetic sinter to form the core is disposed inside the mold. By subsequently providing the coil to surround this spacer pin, and injecting the composite material having a different permeability from that of the magnetic sinter, and then molding, an inductor having a coil and a spacer pin embedded as a core inside the molded body is obtained. Consequently, by adjusting the permeability of the composite material and the magnetic sinter, inductors having various impedances are easily provided. Particularly, as compared with a conventional inductor not having a core including the magnetic sinter, in the present invention a magnetic sinter having a high permeability is disposed within the coil. Therefore the magnetic resistance of the entire body is reduced, and the impedance is greatly increased.

Additionally, in the manufacturing method according to preferred embodiments of the present embodiment, the impedance is increased by the combination of the spacer pin, including a magnetic sinter, and the composite material. Therefore, it is not necessary to increase the content of the powdered magnetic material in the composite material, and, consequently, productivity is increased. Furthermore, since it is not necessary to reduce the diameter of the coil wire, deterioration in the current-carrying capacity is prevented.

In addition, in the inductor according to preferred embodiments of the present invention, the core including the magnetic sinter and the coil which encloses the core are embedded inside the molded body including the composite material. Also, external electrodes are provided on the outside surfaces of the molded body such that both ends of the coil are electrically connected to the electrodes. Therefore, by adjusting the combination of the composite material and the core including the magnetic sinter, the impedance is easily adjusted to various values.

Additionally, the inductor includes a core including the magnetic sinter. Therefore, the magnetic resistance of the entire body is decreased, and thus, the impedance is increased. Thus, inductors having various impedance values, especially those having high impedance, are provided without reducing the current-carrying capacity or the productivity thereof.

While the present invention has been described with reference to what are at present considered to be preferred embodiments, it is to be understood that various changes and modifications may be made thereto without departing from the invention in its broader aspects and therefore, it is intended that the appended claims cover all such changes and modifications that fall within the true spirit and scope of the invention.

What is claimed is:

1. A method of manufacturing an inductor, comprising the steps of:
providing a spacer pin which defines a core, and which includes a magnetic sinter, in a mold;
placing a coil on the spacer pin so as to surround the spacer pin;
injecting into the mold a composite material which has a permeability that is different from that of the magnetic sinter and which includes a mixture of a powdered magnetic material and a resin, to thereby obtain a molded body having embedded therein the coil and the spacer pin; and
forming external electrodes on outside surfaces of the molded body such that both ends of the coil are connected to the external electrodes.

2. A method according to claim 1, wherein a spacer-pin insertion hole for inserting the spacer pin into the mold is provided in the mold, and wherein the spacer pin is pushed by a next spacer pin via the spacer-pin insertion hole and is disposed inside the mold.

3. A method according to claim 1, wherein the coil is defined by a wound insulated conductor wire.

4. A method according to claim 3, wherein the wound insulated conductor wire is tightly wound such that there are no gaps between respective turns of the coil.

5. A method according to claim 3, wherein the insulated conductor wire is made of one of copper, silver and gold.

6. A method according to claim 1, wherein a resin-injecting hole is provided in the mold for injecting the composite material into the mold.

7. A method according to claim 1, wherein the resin is a synthetic resin selected from the group consisting of polyphenylene sulphide, liquid crystal polymer, and polyacetal.

8. A method of manufacturing an inductor, comprising the steps of:
preparing a mold comprising a lower mold portion and an upper mold portion, defining a cavity therebetween, the lower mold having a spacer-pin insertion hole provided therein for inserting a spacer pin made of a magnetic sinter through the lower mold portion;
inserting the spacer pin via the spacer-pin insertion hole through the lower mold portion;
disposing a coil in the lower mold portion, the spacer-pin insertion hole being located at an approximate center of the lower mold portion;
inserting the spacer pin into the molding cavity defined by the upper mold portion and the lower mold portion, and injecting a composite material, which includes a magnetic material and a resin, into the molding cavity while the coil is disposed around the spacer pin, thereby obtaining a molded body having embedded therein the spacer pin and the coil; and
forming external electrodes on outside surfaces of the molded body after the molded body is removed from the mold.

9. A method according to claim 8, wherein the coil is defined by a wound insulated conductor wire.

10. A method according to claim 9, wherein the wound insulated conductor wire is tightly wound such that there are no gaps between respective turns of the coil.

11. A method according to claim 9, wherein the insulated conductor wire is made of one of copper, silver and gold.

12. A method according to claim 8, wherein a resin-injecting hole is provided in the lower mold portion for injecting the composite material into the mold.

13. A method according to claim 8, wherein the resin is a synthetic resin selected from the group consisting of polyphenylene sulphide, liquid crystal polymer, and polyacetal.

14. An inductor comprising:
a molded body included a molded composite material including a mixture of a powdered magnetic material and a resin;
a core embedded in the molded body, the core including a magnetic sinter that has a permeability that is different from that of the composite material constituting the molded body;
a coil arranged so as to surround the core and embedded in the molded body such that both ends of the coil are exposed at the outside surfaces of the molded body; and
a plurality of external electrodes disposed on the outside surfaces of the molded body such that both ends of the coil are electrically connected to the electrodes.

15. An inductor according to claim 14, wherein the coil is defined by a wound insulated conductor wire.

16. An inductor according to claim 15, wherein the wound insulated conductor wire is tightly wound such that there are no gaps between respective turns of the coil.

17. An inductor according to claim 15, wherein the insulated conductor wire is made of one of copper, silver and gold.

18. An inductor according to claim 14, wherein a resin-injecting hole is provided in the mold for injecting the composite material into the mold.

19. An inductor according to claim 14, wherein the resin is a synthetic resin selected from the group consisting of polyphenylene sulphide, liquid crystal polymer, and polyacetal.
